(19) United States
(12) Patent Application Publication
(10) Pub. No.: US 2009/0195069 A1
(43) Pub. Date: Aug. 6, 2009

(54) SIGNAL TRANSMISSION CIRCUIT

(75) Inventors: Akiyuki Naito, Kariya-shi (JP); Yukio Kato, Kariya-shi (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: KABUSHIKI KAISHA TOYOTA JIDOSHOKKI, Aichi-ken (JP)

(21) Appl. No.: 12/360,509

(22) Filed: Jan. 27, 2009

(30) Foreign Application Priority Data
Jan. 29, 2008 (JP) 2008-018344

(51) Int. Cl. H02J 4/00

(52) U.S. Cl. 307/18

(57) ABSTRACT

A circuit includes a transformer, and primary and secondary circuits. The primary generates a first pulse across the primary coil of the transformer when a first input goes high and a second input goes low, and generates a second pulse when the first and second inputs go high. The primary generates a third pulse when the first and second inputs go low, and generates a fourth pulse when the first input goes low and the second input goes high. A first output from the secondary goes high when a pulse is induced across the secondary coil by the first or second pulse, and goes low when a pulse is induced by the third or fourth pulse. A second output from the secondary goes high when a pulse is induced by the second or fourth pulse, and goes low when a pulse is induced by the first or third pulse.

### CROSS REFERENCE TO RELATED APPLICATIONS

This application claims priority to Japanese Patent Application No. 2008-018344 filed on Jan. 29, 2008.

### BACKGROUND

The present invention relates to a signal transmission circuit that transmits a signal from an input side to an output side while keeping the input side electrically isolated from the output side.

In a known signal transmission circuit, for example, a photocoupler is used to electrically isolate the input side from the output side. However, due to large transmission delay of the photocoupler, transmission delay of a digital signal in such circuit is also large. In addition, since the photocoupler cannot be used in an environment at a temperature of 100 degrees C. or more, the circuit also cannot be used in such environment.

To solve above problems with the photocoupler, for example, a transformer is used in the circuit to electrically isolate the input side from the output side. FIG. 9 is a schematic diagram of a known signal transmission circuit using a transformer.

The circuit 90 of FIG. 9 includes a primary circuit 91, a secondary circuit 92 and a transformer 93. The transformer 93 has a primary coil and a secondary coil. When a signal (an input signal) is inputted to the primary circuit 91, the transformer 93 transmits the signal from the primary circuit 91 to the secondary circuit 92 while keeping the primary circuit 91 electrically isolated from the secondary circuit 92. The secondary circuit 92 then outputs a corresponding signal (an output signal).

In the circuit 90, for example, a temperature input signal and a FAIL input signal are processed. The temperature input signal indicating a temperature is outputted from a temperature detection circuit (not shown in the drawing), and the FAIL input signal indicating a failure is outputted from a failure detection circuit (not shown in the drawing). The temperature and FAIL input signals are inputted to the primary circuit 91 and transmitted to the secondary circuit 92 via the transformer 93. Then corresponding temperature and FAIL output signals are outputted from the secondary circuit 92.

Another known circuit is disclosed in Japanese Unexamined Patent Application Publication No. 2006-280100. In the circuit, a pulse voltage is constantly applied to the primary coil of the transformer in a given cycle. While an input signal is high, a pulse voltage applied to the primary coil is to be lowered. Accordingly, a pulse voltage across the secondary coil becomes low, and signal from the circuit outputs high. Such circuit can transmit two different signals from the primary circuit to the secondary circuit via the transformer, as with the above circuit 90. Specifically, a pulse voltage level applied to the primary coil is changed in response to kinds of input signals, and an output signal from the circuit is changed in response to a pulse voltage level induced across the secondary coil.

As described above, there are various circuit configurations to transmit plural input signals from the primary circuit to the secondary circuit via the transformer. Therefore, the present invention is directed to a signal transmission circuit with new configuration that can transmit plural input signals from an input side to an output side via a transformer.

### SUMMARY

In accordance with an aspect of the present invention, a signal transmission circuit includes a transformer, a primary circuit and a secondary circuit. The transformer has a primary coil and a secondary coil. The primary circuit is connected to the primary coil and inputs a first input signal and a second input signal. The primary circuit generates a first pulse voltage across the primary coil when the first input signal goes high and the second input signal goes low. The primary circuit generates a second pulse voltage across the primary coil when the first and second input signals go high. The second pulse voltage has a same polarity as the first pulse voltage and has a different width from the first pulse voltage. The primary circuit generates a third pulse voltage across the primary coil when the first and second input signals go low. The third pulse voltage has an opposite polarity to the first pulse voltage. The primary circuit generates a fourth pulse voltage across the primary coil when the first input signal goes low and the second input signal goes high. The fourth pulse voltage has an opposite polarity to the first pulse voltage and has a different width from the first pulse voltage. The secondary circuit is connected to the secondary coil. The secondary circuit outputs a first output signal in response to the first input signal and outputs a second output signal in response to the second input signal. The first output signal goes high when a pulse voltage is induced across the secondary coil by the first or second pulse voltage. The first output signal goes low when a pulse voltage is induced across the secondary coil by the third or fourth pulse voltage. The second output signal goes high when a pulse voltage is induced across the secondary coil by the second or fourth pulse voltage. The second output signal goes low when a pulse voltage is induced across the secondary coil by the first or third pulse voltage.

In accordance with another aspect of the present invention, a method for transmitting a signal through a circuit including a transformer, a primary circuit and a secondary circuit. The transformer has a primary coil and a secondary coil. The primary circuit is connected to the primary coil and inputs a first input signal and a second input signal. The secondary circuit is connected to the secondary coil and outputs a first output signal and a second output signal. The method includes the step of generating a pulse voltage across the primary coil by the primary circuit. The pulse voltage has a first polarity when the first input signal goes high. The pulse voltage has a second polarity opposite to the first polarity when the first input signal goes low. The pulse voltage has a first width when the second input signal goes high. The pulse voltage has a second width different from the first width when the second input signal goes low. The method further includes the step of determining whether the first input signal is high or low based on a polarity of a pulse voltage induced across the secondary coil and then outputting the corresponding first output signal from the secondary circuit. The method further includes the step of determining whether the second input signal is high or low based on a width of a pulse voltage induced across the secondary coil and then outputting the corresponding second output signal from the secondary circuit.

Other aspects and advantages of the invention will become apparent from the following description, taken in conjunction with the accompanying drawings, illustrating by way of example the principles of the invention.

### BRIEF DESCRIPTION OF THE DRAWINGS

The features of the present invention that are believed to be novel are set forth with particularity in the appended claims. The invention together with objects and advantages thereof, may best be understood by reference to the following description of the presently preferred embodiments together with the accompanying drawings in which:

FIG. 1 is a schematic diagram of a signal transmission circuit according to a first embodiment of the present invention;

FIG. 2 is a schematic block diagram of a power supply driver of the signal transmission circuit of the first embodiment;

FIG. 3 is a schematic block diagram of a reconstruction circuit of the signal transmission circuit of the first embodiment;

FIG. 4 is a timing chart of outputs from respective circuits in the signal transmission circuit of the first embodiment;

FIG. 5 is a timing chart to explain a problem with the circuit of the first embodiment;

FIG. 6 is a schematic block diagram of a power supply driver of a signal transmission circuit according to a second embodiment of the present invention;

FIG. 7 is a timing chart of outputs from respective circuits in the signal transmission circuit of the second embodiment;

FIG. 8 is a timing chart showing a voltage between nodes A and B in the signal transmission circuit of both embodiments; and

FIG. 9 is a schematic diagram of a known signal transmission circuit.

### DETAILED DESCRIPTION OF ILLUSTRATIVE EMBODIMENTS

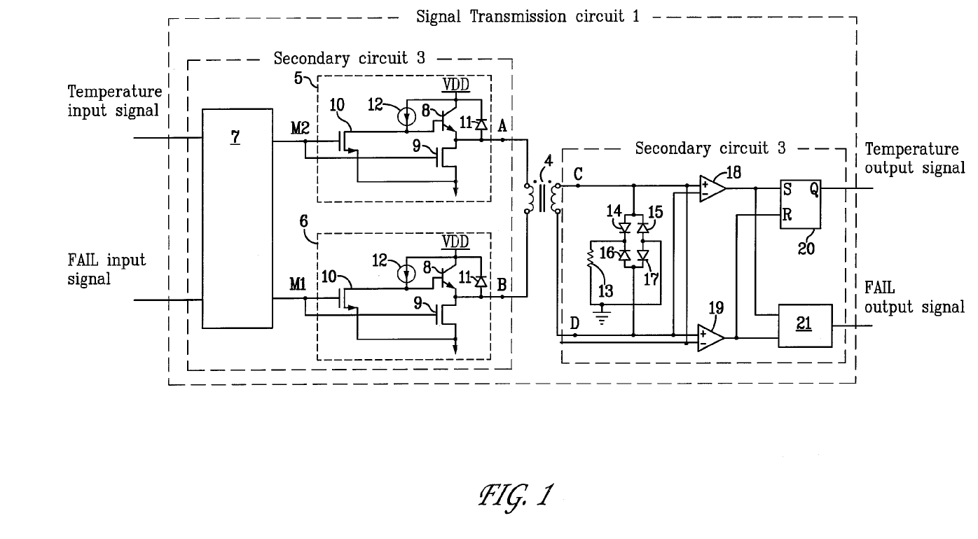

The following will describe the embodiments of the present invention with reference to the attached drawings. Referring to FIG. 1, the signal transmission circuit 1 has a primary circuit 2, a secondary circuit 3 and a transformer 4.

The primary circuit 2 includes power supply circuits 5 and 6, and a power supply driver 7. The power supply circuits 5 and 6 each includes an NPN bipolar transistor 8, n-channel MOSFETs 9 and 10, a diode 11 and a constant current source 12.

A collector of the transistor 8 is connected to a power supply (a voltage VDD) and a cathode of the diode 11, and is connected via the constant current source 12 to a drain of the MOSFET 10 and a base of the transistor 8. An emitter of the transistor 8 is connected to a drain of the MOSFET 9 and an anode of the diode 11. Gates of the MOSFETs 9 and 10 are connected to each other, and sources of the MOSFETs 9 and 10 are grounded. A connection between the transistor 8 and the MOSFET 9 in the power supply circuit 5 is connected to one of the ends of the primary coil of the transformer 4. A connection between the transistor 8 and the MOSFET 9 in the power supply circuit 6 is connected to the other end of the primary coil of the transformer 4.

Hereinafter, the one end of the primary coil of the transformer 4 (a node to be connected to the power supply circuit 5) is referred to as a node A, and the other end of the primary coil (a node to be connected to the power supply circuit 6) is referred to as a node B.

The secondary circuit 3 includes a resistance 13, diodes 14 to 17, comparators 18 and 19, an RS flip-flop 20 and a reconstruction circuit 21.

A positive input terminal of the comparator 18 is connected to one of the ends of the secondary coil of the transformer 4 and a negative input terminal of the comparator 19. An output terminal of the comparator 18 is connected to an input terminal S of the flip-flop 20 and one of the input terminals of the reconstruction circuit 21. A positive input terminal of the comparator 19 is connected to the other end of the secondary coil of the transformer 4 and a negative input terminal of the comparator 18. An output terminal of the comparator 19 is connected to a reset terminal R of the flip-flop 20 and the other input terminal of the reconstruction circuit 21. An anode of the diode 14 is connected to the positive input terminal of the comparator 18 and a cathode of the diode 15. A cathode of the diode 14 is connected to a cathode of the diode 16 and one of the ends of the resistance 13. An anode of the diode 16 is connected to the positive input terminal of the comparator 19 and a cathode of the diode 17. An anode of the diode 17 is connected to an anode of the diode 15 and the other end of the resistance 13, and is grounded.

In the signal transmission circuit 1 of the first embodiment, a temperature input signal (a first input signal) is inputted to the power supply driver 7, and a corresponding temperature output signal (a first output signal) is outputted from an output terminal Q of the flip-flop 20. A FAIL input signal (a second input signal) is inputted to the power supply driver 7, and a corresponding FAIL output signal (a second output signal) is outputted from the reconstruction circuit 21.

Hereinafter, the one end of the secondary coil of the transformer 4 (a node to be connected to the positive input terminal of the comparator 18) is referred to as a node C. The other end of the secondary coil (a node to be connected to the positive input terminal of the comparator 19) is referred to as a node D.

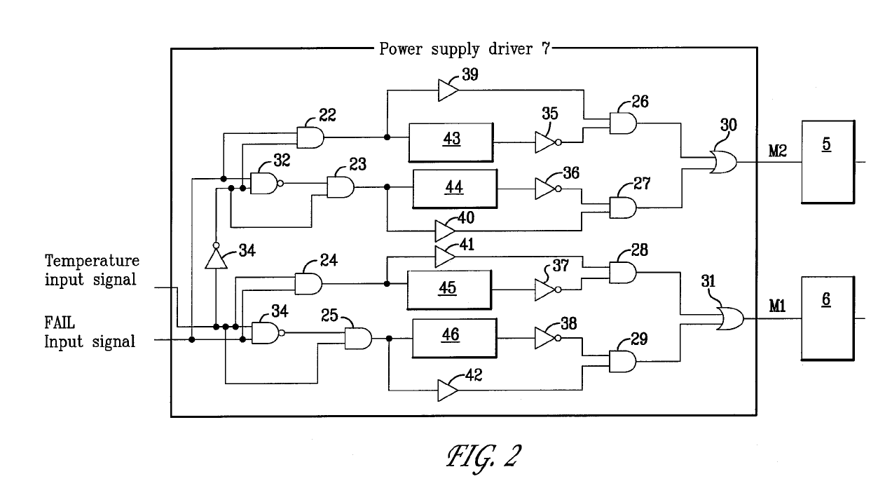

Referring to FIG. 2, the power supply driver 7 includes AND gates 22 to 29, OR gates 30 and 31, NAND gates 32 and 33, inverters 34 to 38, buffers 39 to 42, and delay circuits 43 to 46. The delay circuit 43 has the same delay time A as the delay circuit 45, and the delay circuits 44 has the same delay time B as the delay circuit 46. The delay time A is longer than the delay time B. For example, the delay time A is set to 300 ns, and the delay time B is set to 100 ns.

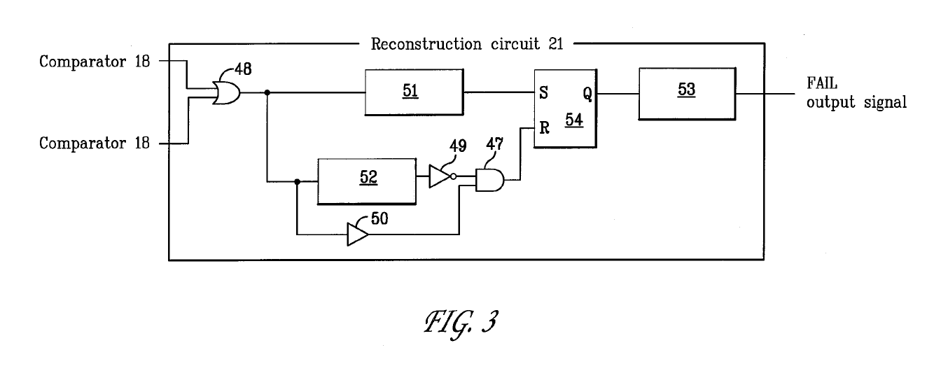

Referring to FIG. 3, the reconstruction circuit 21 includes an AND gate 47, an OR gate 48, an inverter 49, a buffer 50, delay circuits 51 to 53, and an RS flip-flop 54.

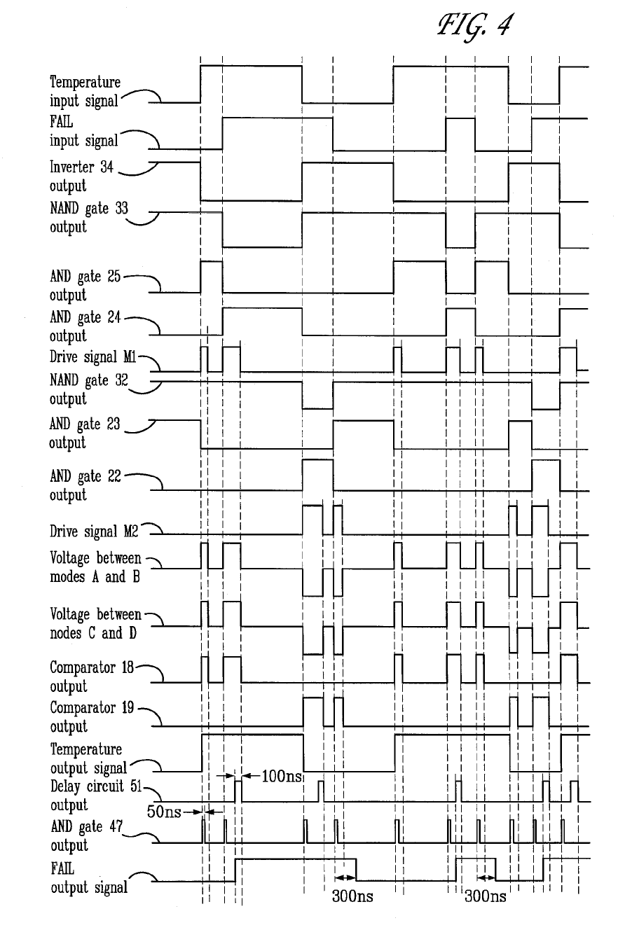

FIG. 4 is a timing chart of outputs from respective circuits in the signal transmission circuit 1. A drive signal M1 is an output from the power supply driver 7 to turn on the MOSFETs 9 and 10 of the power supply circuit 6, and a drive signal M2 is an output from the power supply driver 7 to turn on the MOSFETs 9 and 10 of the power supply circuit 5. High and low periods of the temperature and FAIL input signals are sufficiently longer than pulse widths of the drive signals M1 and M2. Hereinafter, base-emitter voltage of the transistor 8 is referred to as Vbe, and threshold voltage of the diode 11 is referred to as VF.

The following will describe the operation of the signal transmission circuit 1 at the time when a temperature input signal goes high and low.

When a temperature input signal goes high while a FAIL input signal remains low, both outputs from the NAND gate 33 and the AND gate 25 go high, in the power supply driver 7 of FIG. 2. The high output from the AND gate 25 is delayed by the delay circuit 46 with the delay time B, inverted by the inverter 38, and then inputted to one of the input terminals of the AND gate 29. The high output from the AND gate 25 is also inputted to the other input terminal of the AND gate 29 via the buffer 42. As a result, a pulse voltage with a width equal to the delay time B is outputted as a drive signal M1 from the AND gate 29 to the power supply circuit 6 via the OR gate 31.

When the pulse voltage with a width equal to the delay time B is inputted to the power supply circuit 6 (while a drive signal M2 is low), the transistor 8 of the power supply circuit 5 and the MOSFET 9 of the power supply circuit 6 turn on, and the MOSFET 9 of the power supply circuit 5 and the transistor 8 of the power supply circuit 6 turn off (see FIG. 1). In such a case, an electric potential at the node B in the primary circuit 2 becomes grounded, and an electric potential at the node A in the primary circuit 2 becomes VDD minus Vbe. As a result, a positive pulse voltage with a width equal to the delay time B (a first pulse voltage) is generated between the nodes A and B in the primary circuit 2 (that is, on the primary coil of the transformer 4). Then a corresponding pulse voltage is induced via the transformer 4 between the nodes C and D in the secondary circuit 3 (that is, on the secondary coil of the transformer 4). The induced voltage to be inputted to the comparator 18 is larger than a threshold of the comparator 18 (a first threshold), and therefore an output from the comparator 18 goes high.

The high output level from the comparator 18 is inputted to the input terminal S of the flip-flop 20, and then a temperature output signal from the output terminal Q of the flip-flop 20 goes high.

When a temperature input signal goes high while a FAIL input signal remains high, an output from the AND gate 24 goes high. The high output from the AND gate 24 is delayed by the delay circuit 45 with the delay time A, inverted by the inverter 37, and then inputted to one of the input terminals of the AND gate 28. The high output from the AND gate 24 is also inputted to the other input terminal of the AND gate 28 via the buffer 41. As a result, a pulse voltage with a width equal to the delay time A is outputted as a drive signal M1 from the AND gate 28 to the power supply circuit 6 via the OR gate 31.

When the pulse voltage with a width equal to the delay time A is inputted to the power supply circuit 6 (while a drive signal M2 is low), the transistor 8 of the power supply circuit 5 and the MOSFET 9 of the power supply circuit 6 turn on, and the MOSFET 9 of the power supply circuit 5 and the transistor 8 of the power supply circuit 6 turn off. In such a case, an electric potential at the node B in the primary circuit 2 becomes grounded, and an electric potential at the node A in the primary circuit 2 becomes VDD minus Vbe. As a result, a positive pulse voltage with a width equal to the delay time A (a second pulse voltage) is generated between the nodes A and B, and a corresponding pulse voltage is induced via the transformer 4 between the nodes C and D. The induced voltage to be inputted to the comparator 18 is also larger than the threshold of the comparator 18, and therefore an output from the comparator 18 goes high.

The high output level from the comparator 18 is inputted to the input terminal S of the flip-flop 20, and then a temperature output signal from the output terminal Q of the flip-flop 20 goes high.

When a temperature input signal goes low while a FAIL input signal remains low, the temperature input signal is inverted by the inverter 34, and therefore one of the inputs of the NAND gate 32 goes high. Since the FAIL input signal, that is, the other input of the NAND gate 32 is low, both outputs from the NAND gate 32 and the AND gate 23 go high. The high output from the AND gate 23 is delayed by the delay circuit 44 with the delay time B, inverted by the inverter 36, and then inputted to one of the input terminals of the AND gate 27. The high output from the AND gate 23 is also inputted to the other input terminal of the AND gate 27 via the buffer 40. As a result, a pulse voltage with a width equal to the delay time B is outputted as a drive signal M2 from the AND gate 27 to the power supply circuit 5 via the OR gate 30.

When the pulse voltage with a width equal to the delay time B is inputted to the power supply circuit 5 (while a drive signal M1 is low), the MOSFET 9 of the power supply circuit 5 and the transistor 8 of the power supply circuit 6 turn on, and the transistor 8 of the power supply circuit 5 and the MOSFET 9 of the power supply circuit 6 turn off. In such a case, an electric potential at the node A in the primary circuit 2 becomes grounded, and an electric potential at the node B in the primary circuit 2 becomes VDD minus Vbe. As a result, a negative pulse voltage with a width equal to the delay time B (a third pulse voltage) is generated between the nodes A and B, and a corresponding pulse voltage is induced via the transformer 4 between the nodes C and D. The induced voltage to be inputted to the comparator 19 is larger than a threshold of the comparator 19 (a second threshold), and therefore an output from the comparator 19 goes high.

The high output level from the comparator 19 is inputted to the reset terminal R of the flip-flop 20, and then a temperature output signal from the output terminal Q of the flip-flop 20 goes low.

When a temperature input signal goes low while a FAIL input signal remains high, an output from the AND gate 22 goes high. The high output from the AND gate 22 is delayed by the delay circuit 43 with the delay time A, inverted by the inverter 35, and then inputted to one of the input terminals of the AND gate 26. The high output from the AND gate 22 is also inputted to the other input terminal of the AND gate 26 via the buffer 39. As a result, a pulse voltage with a width equal to the delay time A is outputted as a drive signal M2 from the AND gate 26 to the power supply circuit 5 via the OR gate 30.

When the pulse voltage with a width equal to the delay time A is inputted to the power supply circuit 5, the MOSFET 9 of the power supply circuit 5 and the transistor 8 of the power supply circuit 6 turn on, and the transistor 8 of the power supply circuit 5 and the MOSFET 9 of the power supply circuit 6 turn off. In such a case, an electric potential at the node A in the primary circuit 2 becomes grounded, and an electric potential at the node B in the primary circuit 2 becomes VDD minus Vbe. As a result, a negative pulse voltage with a width equal to the delay time A (a fourth pulse voltage) is generated between the nodes A and B, and a corresponding pulse voltage is induced via the transformer 4 between the nodes C and D. The induced voltage to be inputted to the comparator 19 is also larger than the threshold of the comparator 19, and therefore an output from the comparator 19 goes high.

The high output level from the comparator 19 is inputted to the reset terminal R of the flip-flop 20, and then a temperature output signal from the output terminal Q of the flip-flop 20 goes low.

The thresholds of the comparators 18 and 19 are set in such a manner that a voltage between the nodes C and D is larger than Vbe plus VF and smaller than VDD minus Vbe.

As described above, the signal transmission circuit 1 of the first embodiment outputs a temperature output signal via the transformer 4 in response to a temperature input signal. The temperature output signal is outputted at the same timing as the temperature input signal goes high and low.

The following will describe the operation of the signal transmission circuit 1 at the time when a FAIL input signal goes high and low.

When a FAIL input signal goes high while a temperature input signal remains high, an output from the AND gate 24 goes high. The high output from the AND gate 24 is delayed by the delay circuit 45 with the delay time A, inverted by the inverter 37, and then inputted to one of the input terminals of the AND gate 28. The high output from the AND gate 24 is also inputted to the other input terminal of AND gate 28 via the buffer 41. As a result, a pulse voltage with a width equal to the delay time A is outputted as a drive signal M1 from the AND gate 28 to the power supply circuit 6 via the OR gate 31.

When the pulse voltage with a width equal to the delay time A is inputted to the power supply circuit 6, as described above, a positive pulse voltage with a width equal to the delay time A (the second pulse voltage) is generated between the nodes A and B in the primary circuit 2. Then a corresponding pulse voltage is induced via the transformer 4 between the nodes C and D in the secondary circuit 3, so that an output from the comparator 18 goes high.

The high output level from the comparator 18 is inputted via the OR gate 48 to the delay circuit 51 and delayed with a delay time C (e.g. 200 ns), in the reconstruction circuit 21 of FIG. 3. As a result, a pulse voltage with a width equal to the delay time A minus C (100 ns, where the delay time A is 300 ns, and the delay time C is 200 ns) is outputted from the delay circuit 51. The pulse voltage is inputted to the input terminal S of the flip-flop 54, and then a FAIL output signal from the output terminal Q of the flip-flop 54 via the delay circuit 53 goes high.

When a FAIL input signal goes high while a temperature input signal remains low, an output from the AND gate 22 goes high. The high output from the AND gate 22 is delayed by the delay circuit 43 with the delay time A, inverted by the inverter 35, and then inputted to one of the input terminals of the AND gate 26. The high output from the AND gate 22 is also inputted to the other input terminal of AND gate 26 via the buffer 39. As a result, a pulse voltage with a width equal to the delay time A is outputted as a drive signal M2 from the AND gate 26 to the power supply circuit 5 via the OR gate 30.

When the pulse voltage with a width equal to the delay time A is inputted to the power supply circuit 5, a negative pulse voltage with a width equal to the delay time A (the fourth pulse voltage) is generated between the nodes A and B. Then a corresponding pulse voltage is induced via the transformer 4 between the nodes C and D, so that an output from the comparator 19 goes high.

The high output level from the comparator 19 is inputted via the OR gate 48 to the delay circuit 51 and delayed with the delay time C, so that a pulse voltage with a width equal to the delay time A minus C is outputted from the delay circuit 51. The pulse voltage is inputted to the input terminal S of the flip-flop 54, and then a FAIL output signal from the output terminal Q of the flip-flop 54 via the delay circuit 53 goes high.

When a FAIL input signal goes low while a temperature input signal remains high, both outputs from the NAND gate 33 and the AND gate 25 go high. The high output from the AND gate 25 is delayed by the delay circuit 46 with the delay time B, inverted by the inverter 38, and then inputted to one of the input terminals of the AND gate 29. The high output from the AND gate 25 is also inputted to the other input terminal of AND gate 29 via the buffer 42. As a result, a pulse voltage with a width equal to the delay time B is outputted as a drive signal M1 from the AND gate 29 to the power supply circuit 6 via the OR gate 31.

When the pulse voltage with a width equal to the delay time B is inputted to the power supply circuit 6, a positive pulse voltage with a width equal to the delay time B (the first pulse voltage) is generated between the nodes A and B. Then a corresponding pulse voltage is induced via the transformer 4 between the nodes C and D, so that an output from the comparator 18 goes high.

The high output level from the comparator 18 is inputted via the OR gate 48 to the delay circuit 52. The high output is delayed with a delay time D (e.g. 50 ns), inverted by the inverter 49, and then inputted to one of the input terminals of the AND gate 47. The high output from the comparator 18 is also inputted to the other input terminal of the AND gate 47 via the OR gate 48 and the buffer 50. As a result, a pulse voltage with a width equal to the delay time D is outputted from the AND gate 47 to the reset terminal R of the flip-flop 54, and then an output from the output terminal Q of the flip-flop 54 goes low. The low output from the flip-flop 54 is delayed by the delay circuit 53 with the delay time A and outputted as a FAIL output signal from the reconstruction circuit 21.

When a FAIL input signal goes low while a temperature input signal remains low, the temperature input signal is inverted by the inverter 34, and therefore one of the inputs of the NAND gate 32 is high. Since the FAIL input signal, that is, the other input of the NAND gate 32 goes low, both outputs from the NAND gate 32 and the AND gate 23 go high. The high output from the AND gate 23 is delayed by the delay circuit 44 with the delay time B, inverted by the inverter 36, and then inputted to one of the input terminals of the AND gate 27. The high output from the AND gate 23 is also inputted to the other input terminal of AND gate 27 via the buffer 40. As a result, a pulse voltage with a width equal to the delay time B is outputted as a drive signal M2 from the AND gate 27 to the power supply circuit 5 via the OR gate 30.

When the pulse voltage with a width equal to the delay time B is inputted to the power supply circuit 5, a negative pulse voltage with a width equal to the delay time B (the third pulse voltage) is generated between the nodes A and B. Then a corresponding pulse voltage is induced via the transformer 4 between the nodes C and D, so that an output from the comparator 19 goes high.

The high output level from the comparator 19 is inputted via the OR gate 48 to the delay circuit 52. The high output is delayed with the delay time D, inverted by the inverter 49, and then inputted to one of the input terminals of the AND gate 47. The high output from the comparator 19 is also inputted to the other input terminal of the AND gate 47 via the OR gate 48 and the buffer 50. As a result, a pulse voltage with a width equal to the delay time D is outputted from the AND gate 47 to the reset terminal R of the flip-flop 54, and then an output from the output terminal Q of the flip-flop 54 goes low. The low output from the flip-flop 54 is delayed by the delay circuit 53 with the delay time A and outputted as a FAIL output signal from the reconstruction circuit 21.

As described above, when a FAIL input signal goes high, a wide pulse voltage with a width equal to the delay time A is inputted to the reconstruction circuit 21. In such a case, a pulse voltage with a width equal to the delay time D is inputted from the AND gate 47 to the reset terminal R of the flip-flop 54. Following the input, a pulse voltage with a width equal to the delay time A minus C is inputted from the delay circuit 51 to the input terminal S of the flip-flop 54. As a result, a FAIL output signal from the output terminal Q of the flip-flop 54 goes high.

In addition, when a FAIL input signal goes low, a narrow pulse voltage with a width equal to the delay time B is inputted to the reconstruction circuit 21. In such a case, a pulse voltage with a width equal to the delay time D is inputted from the AND gate 47 to the reset terminal R of the flip-flop 54, but no pulse voltage is inputted to the input terminal S of the flip-flop 54 after the input to the reset terminal R. Therefore, even when a FAIL output signal goes low by the input to the reset terminal R of the flip-flop 54 and then the delay time A elapses, the FAIL output signal from the output terminal Q of the flip-flop 54 does not go high. That is, the FAIL output signal is delayed by the delay circuit 53 with the delay time A. Accordingly, when a FAIL input signal goes low and then the delay time A elapses, a FAIL output signal goes low.

As described above, in the signal transmission circuit 1 of the first embodiment, temperature and FAIL input signals are transmitted from the primary circuit 2 to the secondary circuit 3 via the transformer 4. The secondary circuit 3 then outputs corresponding temperature and FAIL output signals.

In the signal transmission circuit 1, when a temperature input signal goes high, a pulse voltage to be generated across the primary coil of the transformer 4 has a positive polarity (a first polarity). When a temperature input signal goes low, the pulse voltage has a negative polarity (a second polarity). When a FAIL input signal goes high, the pulse voltage has a width equal to the delay time A (a first width). When a FAIL input signal goes low, the pulse voltage has a width equal to the delay time B (a second width).

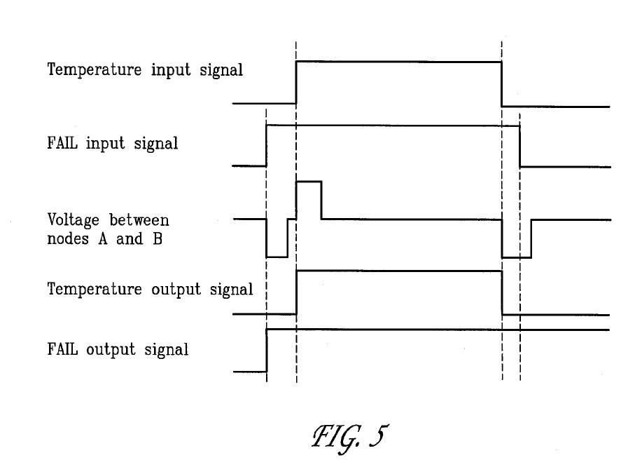

In the signal transmission circuit 1 of the first embodiment, meanwhile, a FAIL input signal may go low just after a temperature input signal goes low, as shown in FIG. 5. When two input signals are thus inputted, it causes that the AND gate 27 of the power supply driver 7 outputs a pulse voltage in response to the FAIL input signal before a pulse voltage from the AND gate 26 goes low in response to the temperature input signal. As a result, a pulse voltage generated between the nodes A and B in response to the temperature input signal may be overlapped with a pulse voltage generated between the nodes A and B in response to the FAIL input signal. In such a case, after a pulse voltage is inputted to the input terminal S of the flip-flop 54 of the reconstruction circuit 21, no pulse voltage is inputted to the reset terminal R of the flip-flop 54, accordingly a FAIL output signal from the flip-flop 54 does not go low.

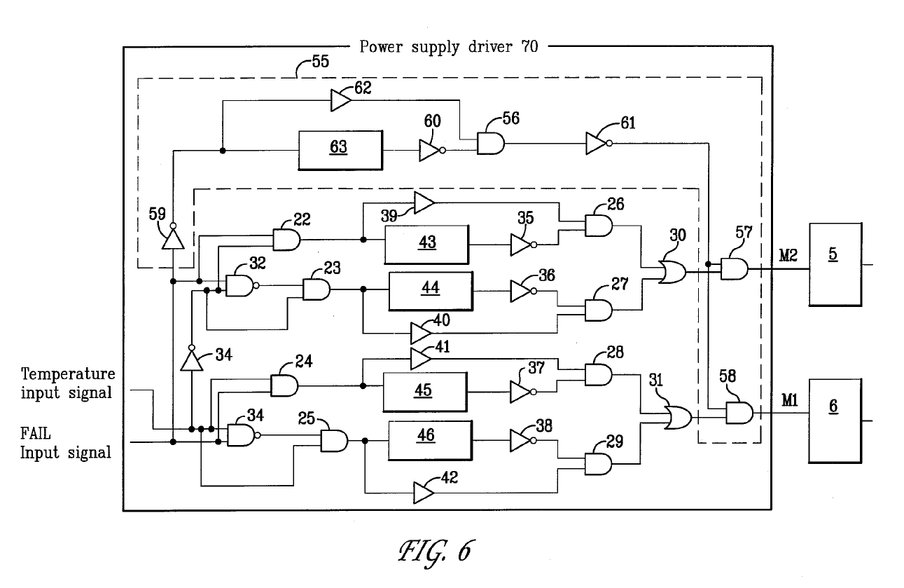

To solve such problem, the second embodiment of the present invention is provided. FIG. 6 is a schematic block diagram of a power supply driver of the second embodiment. In FIG. 6, the same reference numbers are used for the common elements or components in both embodiments (see FIG. 2).

Referring to FIG. 6, the power supply driver 70 includes the AND gates 22 to 29, the OR gates 30 and 31, the NAND gates 32 and 33, the inverters 34 to 38, the buffers 39 to 42, and the delay circuits 43 to 46 of the first embodiment and further a false operation prevention circuit 55.

The false operation prevention circuit 55 includes AND gates 56 to 58, inverters 59 to 61, a buffer 62, and a delay circuit 63.

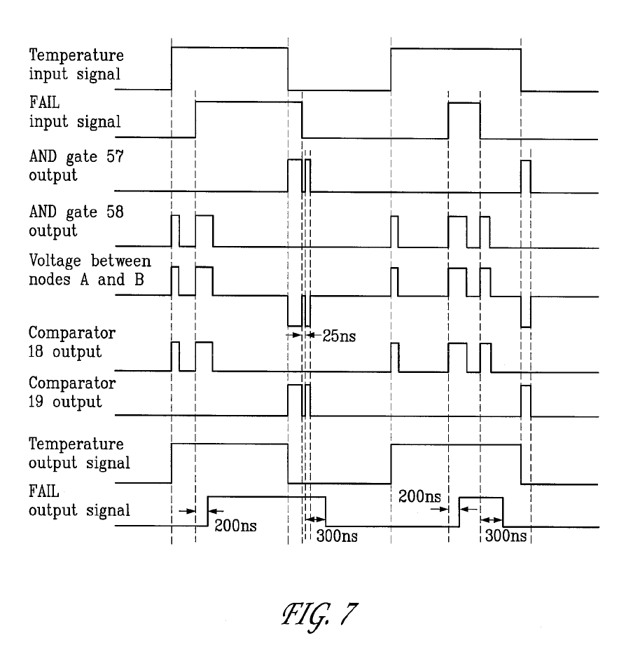

FIG. 7 is a timing chart of outputs from the respective circuits in the signal transmission circuit of the second embodiment.

When a FAIL input signal goes low, a high output from the inverter 59 of the false operation prevention circuit 55 is delayed by the delay circuit 63 with a predetermined time (e.g. 25 ns), inverted by the inverter 60, and then inputted to one of the input terminals of the AND gate 56. The high output from the inverter 59 is also inputted to the other input terminal of the AND gate 56 via the buffer 62, so that a pulse voltage with a width equal to the predetermined time is outputted from the AND gate 56. The pulse voltage from the AND gate 56 is inverted by the inverter 61 to go low, and then inputted to one of the input terminals of the AND gates 57 and 58. The other input of the AND gate 57 is a pulse voltage from the OR gate 30, and the other input of the AND gate 58 is a pulse voltage from the OR gate 31.

As described above, when a FAIL input signal goes low just after a temperature input signal goes low, a pulse voltage from the AND gate 26 may be overlapped with a pulse voltage from the AND gate 27. That is, only one pulse voltage may be outputted from the OR gate 30. According to the second embodiment, however, since the low output with a width equal to the predetermined time is outputted from the inverter 61 to the AND gate 57, a pulse voltage from the OR gate 30 is divided into two pulse voltages. In such a case, a pulse voltage is inputted to the reset terminal R of the flip-flop 54 of the reconstruction circuit 21 by the second of such two pulse voltages, so that a FAIL output signal from the flip-flop 54 goes low as a FAIL input signal goes low.

As described above, in the signal transmission circuit of the second embodiment, a FAIL input signal is transmitted more reliably from the primary circuit 2 to the secondary circuit 3 via the transformer 4 thereby to be outputted as a FAIL output signal.

The following will describe the operation of the signal transmission circuit of the above embodiments at the time just after a positive pulse voltage between the nodes A and B goes low. The positive pulse voltage is generated when a temperature input signal goes high and when a FAIL input signal goes high or low.

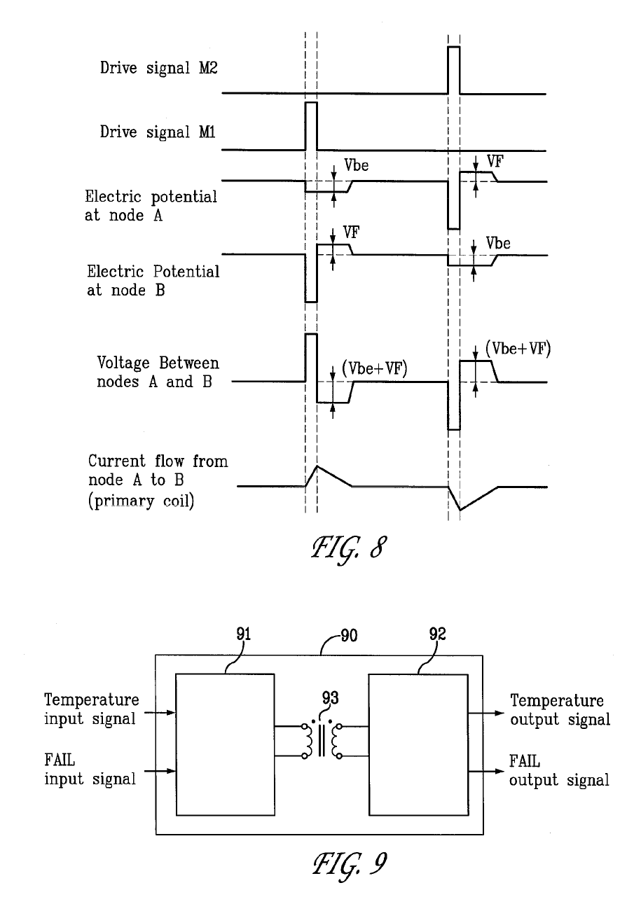

As shown in FIG. 8, when a drive signal M1 goes low, a positive pulse voltage between the nodes A and B goes low. In such a case, the one end of the primary coil of the transformer 4 (the node A) is connected via the transistor 8 of the power supply circuit 5 to the power supply (VDD) of the power supply circuit 5. The other end of the primary coil (the node B) is connected via the diode 11 of the power supply circuit 6 to the power supply (VDD) of the power supply circuit 6, so that a negative voltage (−VF−Vbe) is generated between the nodes A and B. While the positive pulse voltage is generated, current flows in the order from the power supply (VDD) of the power supply circuit 5 through the transistor 8 of the power supply circuit 5, the primary coil of the transformer 4, and the MOSFET 9 of the power supply circuit 6 to ground of the power supply circuit 6. When the negative voltage is generated, current flows in the order from the power supply (VDD) of the power supply circuit 5 through the transistor 8 of the power supply circuit 5, the primary coil of the transformer 4, and the diode 11 of the power supply circuit 6 to the power supply (VDD) of the power supply circuit 6. As a result, since the stored energy in the transformer 4 is reset, no current flows through the transformer 4, and each electric potential at the nodes A and B becomes VDD.

The above negative voltage generated between the nodes A and B (−VF−Vbe) is set to such a value that an output from the comparator 19 does not go high. That is, the negative voltage is smaller than the second threshold of the comparator 19.

The following will describe the operation of the signal transmission circuit of the above embodiments at the time just after a negative pulse voltage between the nodes A and B goes low. The negative pulse voltage is generated when a temperature input signal goes low and when a FAIL input signal goes high or low.

As shown in FIG. 8, when a drive signal M2 goes low, a negative pulse voltage between the nodes A and B goes low. In such a case, the one end of the primary coil of the transformer 4 (the node A) is connected via the diode 11 of the power supply circuit 5 to the power supply (VDD) of the power supply circuit 5. The other end of the primary coil (the node B) is connected via the transistor 8 of the power supply circuit 6 to the power supply (VDD) of the power supply circuit 6, so that a positive voltage (VF+Vbe) is generated between the nodes A and B. While the negative pulse voltage is generated, current flows in the order from the power supply (VDD) of the power supply circuit 6 through the transistor 8 of the power supply circuit 6, the primary coil of the transformer 4, the MOSFET 9 of the power supply circuit 5 to ground of the power supply circuit 5. When the positive pulse voltage is generated, current flows in the order from the power supply (VDD) of the power supply circuit 6 through the transistor 8 of the power supply circuit 6, the primary coil of the transformer 4, the diode 11 of the power supply circuit 5 to the power supply (VDD) of the power supply circuit 5. As a result, since the stored energy in the transformer 4 is reset, no current flows through the transformer 4, and each electric potential at the nodes A and B becomes VDD.

The above positive voltage generated between the nodes A and B (VF+Vbe) is set to such a value that an output from the comparator 18 does not go high. That is, the positive voltage is smaller than the first threshold of the comparator 18.

According to the first and second embodiments, the transformer 4 is reset at the time just after the input signal goes high or low. Therefore, even if the coefficient of coupling of the transformer 4 is low, LC oscillation due to the leakage inductance of the transformer 4 and capacitance components of the nodes C and D is prevented, so that circuit malfunction does not occur. In addition, since the transformer 4 is reset automatically when a pulse voltage is inputted to the transformer 4, transformer saturation does not occur.

In the above embodiments, temperature and FAIL input signals are transmitted from the primary circuit 2 to the secondary circuit 3 via the transformer 4, and corresponding temperature and FAIL output signals are outputted from the secondary circuit 3. Alternatively, signals other than the temperature and FAIL input signals may be transmitted from the primary circuit 2 to the secondary circuit 3 via the transformer 4.

In the above embodiments, a narrow pulse voltage may be outputted from the primary circuit 2 when a FAIL input signal goes high, and a wide pulse voltage may be outputted from the primary circuit 2 when a FAIL input signal goes low. In addition, a FAIL output signal may go high when the narrow pulse voltage is inputted to the secondary circuit 3, and a FAIL output signal may go low when the wide pulse voltage is inputted to the secondary circuit 3.

Therefore, the present examples and embodiments are to be considered as illustrative and not restrictive, and the invention is not to be limited to the details given herein but may be modified within the scope of the appended claims.

What is claimed:

1. A signal transmission circuit, comprising:
a transformer having a primary coil and a secondary coil;
a primary circuit connected to the primary coil and inputting a first input signal and a second input signal, the primary circuit generating a first pulse voltage across the primary coil when the first input signal goes high and the second input signal goes low, the primary circuit generating a second pulse voltage across the primary coil when the first and second input signals go high, the second pulse voltage having a same polarity as the first pulse voltage and having a different width from the first pulse voltage, the primary circuit generating a third pulse voltage across the primary coil when the first and second input signals go low, the third pulse voltage having an opposite polarity to the first pulse voltage, the primary circuit generating a fourth pulse voltage across the primary coil when the first input signal goes low and the second input signal goes high, the fourth pulse voltage having an opposite polarity to the first pulse voltage and having a different width from the first pulse voltage; and
a secondary circuit connected to the secondary coil, the secondary circuit outputting a first output signal in response to the first input signal and outputting a second output signal in response to the second input signal, wherein the first output signal goes high when a pulse voltage is induced across the secondary coil by the first or second pulse voltage, the first output signal goes low when a pulse voltage is induced across the secondary coil by the third or fourth pulse voltage, the second output signal goes high when a pulse voltage is induced across the secondary coil by the second or fourth pulse voltage, and the second output signal goes low when a pulse voltage is induced across the secondary coil by the first or third pulse voltage.

2. The signal transmission circuit according to claim 1, wherein the primary circuit includes a first power supply circuit and a second power supply circuit, the first power supply circuit connects one end of the primary coil to one of ground and a power supply, the second power supply circuit connects the other end of the primary coil to the other of the ground and the power supply, and polarities of the first, second, third and fourth pulse voltage are selected by the connection between each end of the primary coil and the ground or the power supply.

3. The signal transmission circuit according to claim 2, wherein the first and second power supply circuits have a transistor and a diode, the transistor is connected to the power supply, the diode is connected in parallel and the reverse direction to the transistor, and current flows through the diode just after a pulse voltage is generated across the primary coil so that the transformer is reset.

4. The signal transmission circuit according to claim 1, wherein the first pulse voltage has a same width as the third pulse voltage, the second pulse voltage has a same width as the fourth pulse voltage, the first pulse voltage or the third pulse voltage have a narrower width than the second pulse voltage or the fourth pulse voltage, and the second output signal from the secondary circuit goes high when a pulse voltage induced across the secondary coil still remains after the elapse of a time equal to the pulse width of the first or third pulse voltage since the first, second, third or fourth pulse voltage is generated.

5. The signal transmission circuit according to claim 1, wherein a pulse voltage generated across the primary coil goes low for a predetermined time when the second input signal goes high or low.

6. A method for transmitting a signal through a circuit including a transformer having a primary coil and a secondary coil, a primary circuit connected to the primary coil and inputting a first input signal and a second input signal, and a secondary circuit connected to the secondary coil and outputting a first output signal and a second output signal, the method comprising the steps of:
generating a pulse voltage across the primary coil by the primary circuit, wherein the pulse voltage has a first polarity when the first input signal goes high, the pulse voltage has a second polarity opposite to the first polarity when the first input signal goes low, the pulse voltage has a first width when the second input signal goes high, and the pulse voltage has a second width different from the first width when the second input signal goes low;
determining whether the first input signal is high or low based on a polarity of a pulse voltage induced across the secondary coil and then outputting the corresponding first output signal from the secondary circuit; and
determining whether the second input signal is high or low based on a width of a pulse voltage induced across the secondary coil and then outputting the corresponding second output signal from the secondary circuit.
